(19) United States
(12) Patent Application Publication
(10) Pub. No.: US 2010/0051790 A1
(43) Pub. Date: Mar. 4, 2010

(54) Image Sensor and Method for Manufacturing the Same

(76) Inventor: JIN HO PARK, Gyeongbuk (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/550,493

(22) Filed: Aug. 31, 2009

(30) Foreign Application Priority Data
Sep. 4, 2008 (KR) 10-2008-0087378

(51) Int. Cl. G02B 6/06; H01L 21/00; G01J 3/51

(52) U.S. Cl. 250/227.2; 438/70; 250/226; 257/E21.536

(57) ABSTRACT

Disclosed are an image sensor and a method for manufacturing the same. The image sensor includes a semiconductor substrate including unit pixels, a metal line and an interlayer dielectric layer formed on the semiconductor substrate, a passivation layer formed on the inter-layer dielectric layer and provided on a surface thereof with lens patterns corresponding to the unit pixels, and lens-type color filters formed on the lens patterns.

### CROSS-REFERENCE TO RELATED APPLICATION

This application claims the benefit under 35 U.S.C. §119 to Korean Patent Application No. 10-2008-0087378, filed on Sep. 4, 2008, which is hereby incorporated by reference in its entirety.

### BACKGROUND

An image sensor is a semiconductor device for converting optical images into electric signals, and is typically classified into a charge coupled device (CCD) image sensor and a CMOS image sensor.

The CMOS image sensor includes a photodiode and a MOS transistor in each unit pixel, and sequentially detects the electric signals of each unit pixel in a switching mode to realize images.

Generally, the image sensor includes a metal interconnection and an interlayer dielectric layer formed on a substrate including unit pixels, and a passivation layer, a color filter array, a planarization layer, and a micro-lens formed on the interlayer dielectric layer.

As the size of such an image sensor is reduced, the light collecting efficiency of a photodiode is gradually reduced. As a result, the image sensor has a limitation in condensing light only by using a micro-lens.

Particularly, as the size of a pixel is reduced, light is diffracted so that cross-talk may occur. In addition, since several layers such as a metal interconnection layer and a color filter are formed between the photodiode and the micro-lens, light is absorbed into the layers, so that the sensitivity of the photodiode may be degraded.

In the case of a micro-lens corresponding to a unit pixel, the thickness of the micro-lens and a color filter may vary according to an incident angle or an incident position of light between the center and the edge of the micro-lens. In other words, when the thickness of the color filter varies with respect to incident light, light transmittance may be changed.

For example, a red color filter receives light having a wavelength of 600 nm to 700 nm. However, since the thickness of the micro-lens of the unit pixel varies between the center and the edge area thereof, the red color filter may receive light having a wavelength of 400 nm to 700 nm.

This is because the thickness of the color filter and the micro-lens varies according to the light incidence angle, so that the selectivity of the light transmittance is degraded. Accordingly, the color filter receives light having a wide wavelength, so that the color filter does not perform the original function thereof.

### BRIEF SUMMARY

An embodiment provides an image sensor and a method for manufacturing the same, in which a color filter has the form of a lens, so that the light sensitivity of a photodiode can be improved.

According to an embodiment, an image sensor includes a semiconductor substrate including unit pixels, a metal line and an interlayer dielectric layer formed on the semiconductor substrate, a passivation layer formed on the inter-layer dielectric layer and provided on a surface thereof with lens patterns corresponding to the unit pixels, and lens-type color filters formed on the lens patterns.

According to an embodiment, a method for manufacturing an image sensor includes forming unit pixels including photodiodes on a semiconductor substrate, forming a metal line and an interlayer dielectric layer on the semiconductor substrate, forming a passivation layer on the interlayer dielectric layer, forming lens patterns by selectively etching a surface of the passivation layer corresponding to the unit pixels, and forming lens-type color filters on a surface of the lens patterns.

### BRIEF DESCRIPTION OF THE DRAWINGS

FIGS. 1 to 6 are cross-sectional views showing a method for manufacturing an image sensor according to an embodiment.

### DETAILED DESCRIPTION

An image sensor and a method for manufacturing the same according to an embodiment will be described with respect to accompanying drawings.

FIG. 6 is a cross-sectional view showing an image sensor according to an embodiment.

An image sensor in accordance with an embodiment of the present invention can include a semiconductor substrate 10 including unit pixels, a metal line 50 and an interlayer dielectric layer 40 formed on the semiconductor substrate 10, a passivation layer 60 formed on the interlayer dielectric layer 40 and provided on the surface thereof with lens patterns 61 corresponding to unit pixels, and lens-type color filters formed on the lens patterns 61.

The lens-type color filters can include first, second, and third lens-type color filters 81, 82, and 83 corresponding to red, green, and blue color filters, respectively.

A pixel dividing pattern 63 is formed between each of the first to third lens-type color filters 81 to 83 to divide the first to third lens-type color filters 81 to 83 according to unit pixels.

Since each lens pattern 61 has a convex spherical shape, the first, second, and third lens-type color filters 81, 82, and 83 may have a convex spherical shape. Accordingly, the first, second, and third lens-type color filters 81, 82, and 83 can serve as both color filters and micro-lenses.

Accordingly, since an additional micro-lens is omitted, the further integration of a device can be achieved due to the thickness reduction of the image sensor. In addition, the absorption and diffraction of light are reduced due to the thickness reduction, so that the sensitivity of the photodiode can be improved.

In addition, since the first, second and third lens-type color filters 81, 82, and 83 can have the same thickness from the center portion thereof to an edge portion thereof, uniform light transmittance can be acquired. Accordingly, the image characteristic of the image sensor can be improved.

Reference numerals of FIG. 6, which are not described, will be described in a method for manufacturing an image sensor provided below.

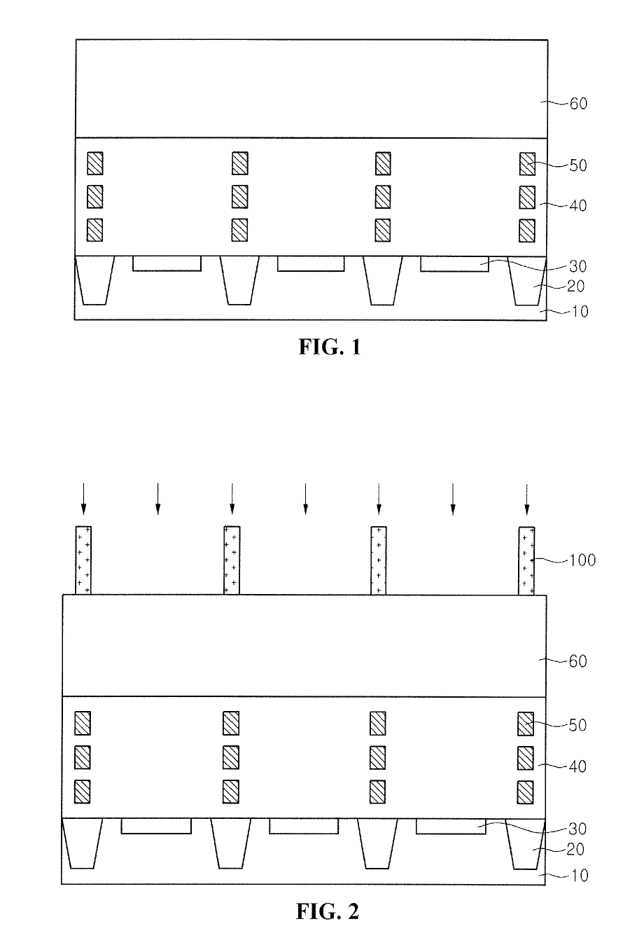

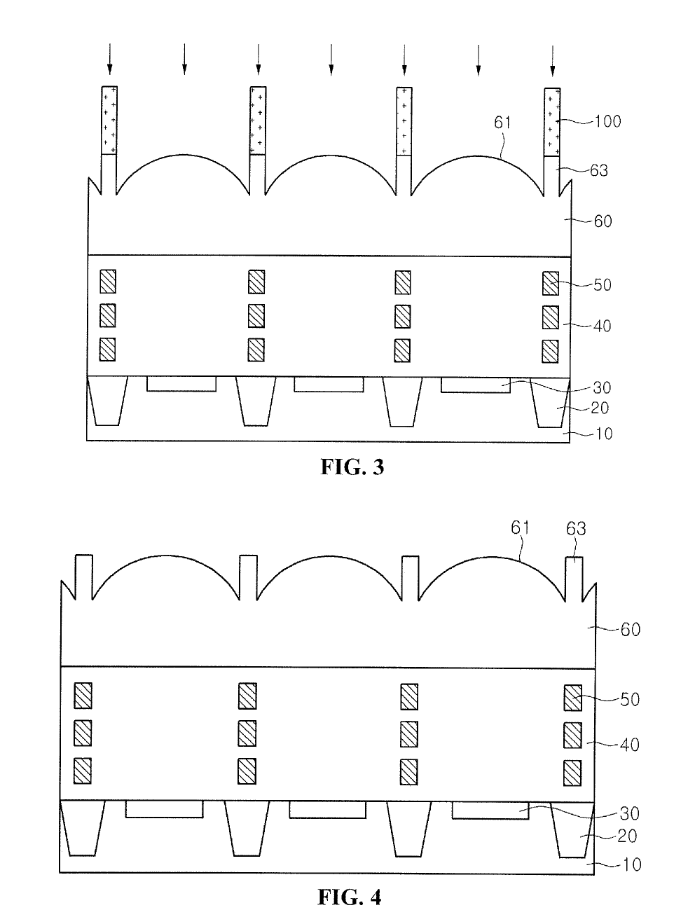

Hereinafter, a method for manufacturing the image sensor according to an embodiment will be described with reference to FIGS. 1 to 6.

FIGS. 1 to 6 are cross-sectional views showing the manufacturing process of an image sensor according to an embodiment.

Referring to FIG. 1, a semiconductor substrate 10 is provided with an isolation layer 20 to define an active area and a field area. A unit pixel formed in the active area includes a photodiode 30 that receives light to generate photo charges and CMOS circuitry (not shown) connected to the photodiode 30 to convert the photo charges into electrical signals.

After related devices including the photodiode 30 have been formed, a metal interconnection layer including a metal interconnection 50 and the interlayer dielectric layer 40 is formed on the semiconductor substrate 10.

The interlayer dielectric layer 40 may include a plurality of layers. For example, the interlayer dielectric layer 40 may include a nitride layer or an oxide layer.

A plurality of metal interconnections 50 may be formed to pass through the interlayer dielectric layer 40. The metal interconnections 50 are intentionally laid out such that light incident on the photodiode 30 is not blocked.

Next, the passivation layer 60 is formed on the interlayer dielectric layer 40. The passivation layer 60 is used to protect devices from moisture or scratches and may include an insulating layer. For example, the passivation layer 60 may include one of a silicon oxide layer, a silicon nitride layer, and a silicon oxide nitride layer. The passivation layer 60 may have a stack structure including at least one layer. According to the embodiment, the passivation layer 60 may be formed by using an USG layer.

Referring to FIG. 2, a photoresist pattern 100 is formed on the passivation layer 60. The photoresist pattern 100 may be formed by coating a photoresist film on the passivation layer 60 and then exposing an area of the photoresist film corresponding to a unit pixel and developing the photoresist film such that the photoresist film remains to expose a light receiving region of each unit pixel. In other words, the photoresist pattern 100 may be formed corresponding to the isolation layer 20 between unit pixels. Meanwhile, the photoresist pattern 100 may be formed by ARF equipment such that the photoresist pattern 100 has a 90 nm line.

Referring to FIGS. 2 to 4, an etching process is performed with respect to the passivation layer 60 by using the photoresist pattern 100 as an etch mask. For example, the etching process may be formed by using etching gas such as HBr and Cl₂. During the etching process, the supply amount of HBr can be three times to six times greater than the supply amount of the Cl₂. In an embodiment, the supply amount of HBr can be three times to eight times greater than the supply amount of the Cl₂. According to certain embodiments, the etching process may be performed by applying HBr and Cl₂ in the ratio of 3-8:1. For example, the ratio of HBr to Cl₂ can be 3:1, 4:1, 5:1, 6:1, 7:1, or 8:1.

When the ratio of the HBr to Cl₂, which are the etching gases, are adjusted to the ratio of 3-8:1, a side surface of the passivation layer 60 covered by the photoresist pattern 100 is etched at a higher etch rate than that of the central area of the passivation layer 60. In other words, when considering the etch rate with respect to a unit pixel defined in the passivation layer 60 by the photoresist pattern 100, since the etch rate of an edge area of the unit pixel becomes higher than that of the central area thereof, the passivation layer 60 may have a convex shape in each unit pixel.

Accordingly, the lens pattern 61 having a convex surface is formed in the passivation layer 60 corresponding to each unit pixel. In addition, the pixel dividing pattern 63 is formed by the passivation layer at sides of the lens pattern 61 at the regions that were protected from the etching process by the photoresist pattern 100.

Thereafter, the photoresist pattern 100 may be removed through an ashing process.

As described above, the lens pattern 61 having a spherical surface is formed in the passivation layer 60 corresponding to each unit pixel through a selective etching process. The lens pattern 61 may be divided corresponding to unit pixels by the pixel dividing pattern 63.

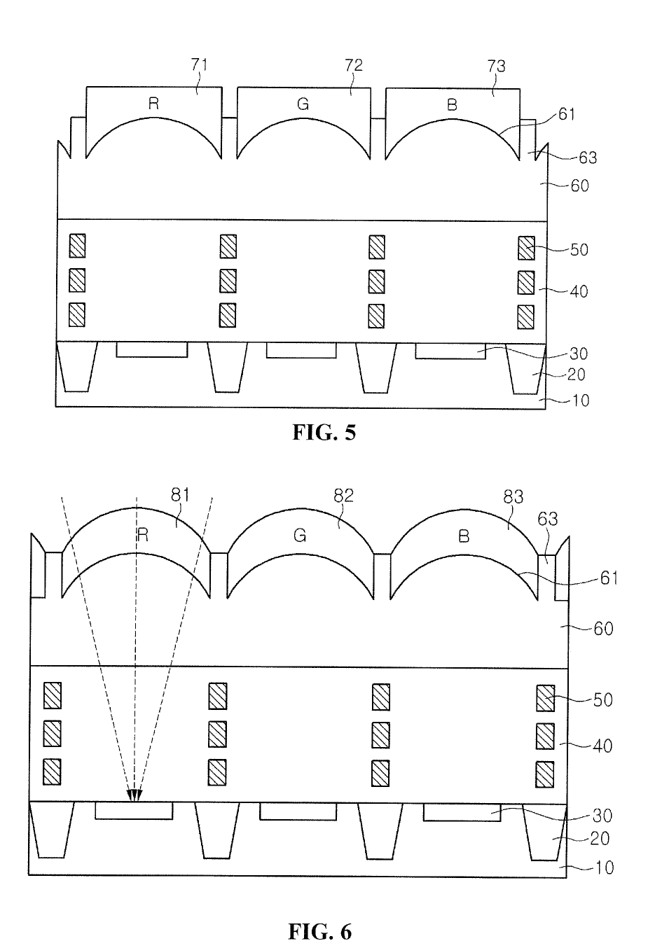

Referring to FIG. 5, color filters are formed on the lens pattern 61 of the passivation layer 60. The color filters may be formed by using dyed photoresist. One color filter is formed in each unit pixel to filter color from incident light.

The color filters have different colors according to unit pixels. The color filters include a first color filter 71, a second color filter 72, and a third color filter 73. For example, the first, second, and third color filters 71, 72, and 73 may be red, green, and blue color filters.

In order to form the first color filter 71, a first color filter layer (not shown) including photoresist material and pigment or photoresist material and dye is formed through a spin coating process. Then, the first color filter layer is subject to an exposure process by using a pattern mask and the first color filter layer is developed, thereby forming the first color filter 71. The second and third color filters 72 and 73 may be formed similarly to the first color filter 71.

The first, second, and third color filters 71, 72, and 73 are formed on the lens pattern 61, which is divided corresponding to unit pixels by the pixel dividing pattern 63, so that the first, second, and third color filters 71, 72, and 73 can be divided corresponding to the unit pixels.

Referring to FIG. 6, a first lens-type color filter 81, a second lens-type color filter 82, and a third lens-type color filter 83 are formed on the lens pattern 61. The first, second, and third lens-type color filters 81, 82, and 83 may be formed through a reflow process for the first, second, and third color filters 71, 72, and 73.

A reflow process is to form a lens surface using surface tension after providing fluidity to polymer material. Accordingly, if the reflow process is performed with respect to the first to third color filters 71 to 73, the first to third lens-type color filters 81 to 83 having a spherical surface are formed.

In detail, in order to form the first to third lens-type color filters 81 to 83, a primary reflow process can be performed for 180 seconds to 220 seconds at a temperature of 170° C. to 190° C., and then a second reflow process can be performed for 160 seconds to 200 seconds at a temperature of 190° C. to 220° C.

In addition, since the first to third color filters 71 to 73 are divided corresponding to unit pixels by the pixel dividing pattern 63, the first to third color filters 71 to 73 are not bridged or merged with each other even if a reflow process is performed. In other words, the pixel dividing pattern 63 is formed between the first to third color filters 71 to 73 to serve as a separator between the first to third color filters 71 to 73. Accordingly, even if the reflow process is performed, the first to third lens-type color filters 81 to 83 are not combined with each other.

After the primary and secondary reflow processes have been performed, the first to third lens-type color filters 81 to 83 may have a convex spherical surface like a typical micro-lens. Accordingly, the first to third lens-type color filters 81 to 83 serve as micro-lenses to condense light into the photodiode 30 of each unit pixel.

In addition, since the first, second, and third lens-type color filters 81, 82 83 are formed by reflowing the first, second, and third color filters 71, 72, and 73, respectively, the first to third lens-type color filters 81 to 83 can serve as color filters.

Accordingly, since the first to third lens-type color filters 81 to 83 can serve as both a micro-lens and a color filter, a process for forming the micro-lens that is a light condensing unit can be omitted. Accordingly, the productivity of the image sensor can be improved due to the simplification of the manufacturing process.

In addition, since the first to third lens-type color filters 81 to 83 can each serve as a lens, the whole thickness of the image sensor can be reduced. Accordingly, the device can be further integrated.

In addition, since the first to third lens-type color filters 81 to 83 each have a hemi-spherical shape along the surface of the lens patterns 61, the first to third lens-type color filters 81 to 83 may have the same thickness at the central area and the edge area thereof. Accordingly, the light sensitivity can be improved. In other words, according to an embodiment, the first lens-type color filter 81 corresponding to one unit pixel is a red filter. The first lens-type color filter 81 has the same thickness at the central area and the edge area thereof, so that the selectivity for light transmittance is equally represented at the central area and the edge area thereof. Accordingly, since only a wavelength of 600 nm to 700 nm can pass through the first lens-type color filter 81, light sensitivity can be improved.

In addition, when comparing with an image sensor according to the related art, since the first to third lens-type color filters 81 to 83 serve as lenses, the thickness of the image sensor according to the embodiment is more reduced, so that light is diffracted better and absorbed. Accordingly, light sensitivity can be improved.

Further, since the first to third lens-type color filters 81 to 83 are divided corresponding to unit pixels by the pixel dividing pattern 63, cross-talk and noise can be reduced.

Further, a focal length between each of the first to third lens-type color filters 81 to 83 and the photodiode 30 is reduced, so that image characteristic can be improved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a semiconductor substrate including unit pixels;
a metal line and an interlayer dielectric layer formed on the semiconductor substrate;
a passivation layer formed on the inter-layer dielectric layer and provided on a surface thereof with lens patterns corresponding to unit pixels; and
lens-type color filters formed on the lens patterns.

2. The image sensor of claim 1, wherein each lens pattern has a convex spherical surface.

3. The image sensor of claim 1, wherein a pixel dividing pattern is formed between the lens patterns.

4. The image sensor of claim 3, wherein the lens patterns include a material identical to a material of the pixel dividing pattern.

5. The image sensor of claim 3, wherein the lens-type color filters are separated according to unit pixels by the pixel dividing pattern.

6. The image sensor of claim 1, wherein a central area of each lens-type color filter of the lens-type color filters has a same thickness as an edge area thereof.

7. A method for manufacturing an image sensor, the method comprising:
forming unit pixels including photodiodes on a semiconductor substrate;
forming a metal line and an interlayer dielectric layer on the semiconductor substrate;
forming a passivation layer on the interlayer dielectric layer;
forming lens patterns by selectively etching a surface of the passivation layer corresponding to unit pixels; and
forming lens-type color filters on the surface of the lens patterns.

8. The method of claim 7, further comprising forming a pixel dividing pattern between the lens patterns, wherein the pixel dividing pattern separates the lens-type color filters according to the unit pixels.

9. The method of claim 8, wherein the forming of the lens patterns and the forming of the pixel dividing pattern comprises:
forming a photoresist pattern such that the passivation layer is exposed at regions corresponding to each unit pixel;
performing an etching process by using the photoresist pattern as a mask to form the lens patterns and the pixel dividing pattern; and
removing the photoresist pattern,
wherein HBr and Cl₂ are supplied in the etching process such that each lens pattern has a convex spherical surface.

10. The method of claim 9, wherein a supply amount of the HBr is three times to six times greater than a supply amount of the Cl₂ in the etching process.

11. The method of claim 9, wherein a supply amount of the HBr is three times to eight times greater than a supply amount of the Cl₂ in the etching process.

12. The method of claim 7, wherein the forming of the lens-type color filters comprises:
forming a color filter on each lens pattern; and
performing a reflow process for the color filters.

13. The method of claim 12, wherein the reflow process comprises a primary and a secondary reflow processes, wherein the primary reflow process is performed at a temperature of 170° C. to 190° C., and the secondary reflow process is performed at a temperature of 190° C. to 220° C.

14. The method of claim 12, wherein a central area of each lens-type color filter of the lens-type color filters has a same thickness as an edge area thereof.
